(19) United States
(12) Patent Application Publication
(10) Pub. No.: US 2026/0111634 A1
(43) Pub. Date: Apr. 23, 2026

(54) USING ARTIFICIAL INTELLIGENCE FOR BUILDING DESIGN SPECIFICATION GENERATION

(71) Applicant: X Development LLC, Mountain View, CA (US)

(72) Inventors: Tal Yarkoni, Concord, CA (US); David Passey, Chapel Hill, NC (US); Julia Black Ling, Menlo Park, CA (US); Christopher Hahn, Palo Alto, CA (US); Sebastian Pilarski, Mountain View, CA (US); Ananya Gupta, San Francisco, CA (US); Adrian James Walker, Oakland, CA (US); Divya Choudhary, San Jose, CA (US); Aaron Bennett Appelle, Mountain View, CA (US)

(21) Appl. No.: 19/425,430

(22) Filed: Dec. 18, 2025

Related U.S. Application Data
(63) Continuation of application No. PCT/US2025/030819, filed on May 23, 2025.
(60) Provisional application No. 63/676,009, filed on Jul. 26, 2024.
(60) Provisional application No. 63/763,386, filed on Feb. 26, 2025.

(51) Int. Cl. G06F 30/27; G06F 30/13

(52) U.S. Cl. CPC G06F 30/27; G06F 30/13

(57) ABSTRACT

Methods, systems, and apparatus, including computer programs encoded on computer-storage media, for automatic generation of building design specifications. Building design data for a plurality of buildings is obtained as building design artificial intelligence model training data. The building design artificial intelligence model training data is enhanced to include building performance specification data corresponding to obtained building design data. An artificial intelligence model is trained using the building design artificial intelligence model training data to generate building design specifications based on building performance specifications. Building performance specifications for a building project are received and provided to the artificial intelligence model that is trained to generate building design specifications based on building performance specifications. The artificial intelligence model generates building designs for the building project that satisfy the building performance specifications. The building designs for the building project are provided for evaluation and construction of the building project.

### CROSS-REFERENCE TO RELATED APPLICATIONS

This application claims the benefit of U.S. Provisional Application No. 63/676,009 filed Jul. 26, 2024, and U.S. Provisional Application No. 63/763,386 filed Feb. 26, 2025, the disclosures of which are incorporated herein in their entireties.

### FIELD

This specification generally relates to artificial intelligence in building construction.

### BACKGROUND

Building construction can involve numerous phases. For instance, a construction project can involve phases such as requirements gathering, site selection, design, and construction.

### SUMMARY

There are many considerations when designing a new building development or a renovation, such as structural soundness, materials costs and other supply chain factors, environmental considerations, financial considerations, community needs, floorplate efficiency, regulatory compliance, and more. Designing optimal building plans to take into account these multifaceted considerations can be challenging and time consuming. In many cases, building development may be substantially slowed by iterative changes to building plans to correct for various considerations as attempts are made to simultaneously satisfy all considerations. As another example, standardized, sub-optimal designs may be repeatedly used due to concerns over efforts to create a good design. An automated AI system can provide an improved approach for generating building designs that meet various input specifications.

One innovative aspect of the subject matter described in this specification is embodied in a method that includes: obtaining, as building design artificial intelligence model training data, building design data for a plurality of buildings; enhancing the building design artificial intelligence model training data to include building performance specification data corresponding to obtained building design data; training an artificial intelligence model using the building design artificial intelligence model training data to generate building design specifications based on building performance specifications; receiving building performance specifications for a building project; providing the building performance specifications to the artificial intelligence model that is trained to generate building design specifications based on building performance specifications; generating, by the artificial intelligence model, building designs for the building project that satisfy the building performance specifications; and providing the building designs for the building project for evaluation and construction of the building project.

Other implementations can include corresponding systems, apparatus, and computer programs, configured to perform the actions of the methods, encoded on computer storage devices. A system of one or more computers can be so configured by virtue of software, firmware, hardware, or a combination of them installed on the system that in operation cause the system to perform the actions. One or more computer programs can be so configured by virtue of having instructions that, when executed by data processing apparatus, cause the apparatus to perform the actions.

The foregoing and other embodiments can each optionally include one or more of the following features, alone or in combination. Obtaining building design data can include obtaining building design data for existing buildings. Obtaining building design data can include generating synthetic data for synthetically-designed buildings. Generating synthetic data can include generating the synthetic data based on a set of rules that includes rules for how buildings can be composed. Enhancing the building design artificial intelligence model training data can include determining the building performance specifications for obtained building design data and associating determined performance specifications, in the building design artificial intelligence model training data, with corresponding building design information. The artificial intelligence model can be trained to generate different kinds of building designs, including structural, architectural, and fixtures-related designs. The artificial intelligence model can be trained to generate one kind of building design information selected from at least structural, architectural, and fixtures-related designs. The artificial intelligence model can be included with other artificial intelligence models in a model cascade in which outputs of some artificial intelligence models are provided as inputs to other artificial intelligence models. Received performance specifications can include multi-modal information including at least textual and image inputs. Operations may include: determining possible bounds for a first performance specification parameter included in received performance specifications; determining that a received value for the first performance specification parameter is outside of the possible bounds for the first performance specification parameter; adjusting the received value for the first performance specification parameter to be within the possible bounds for the first performance specification parameter; and providing an adjusted value for the first performance specification parameter to the artificial intelligence model. A least some of the building design specifications may include vector representations. Operations may include providing the vector representations to a performance evaluation system that evaluates performance of the building design specifications.

The details of one or more implementations are set forth in the accompanying drawings and the description, below. Other potential features and advantages of the disclosure will be apparent from the description and drawings, and from the claims.

### BRIEF DESCRIPTION OF THE DRAWINGS

FIG. 1 illustrates an example system for automatic generation of building design specifications.

FIG. 2A illustrates an example system for training, tuning, and aligning a system for automatic generation of building design specifications.

FIG. 2B is a flowchart of an example method for generating an aligned artificial intelligence model for generating building design specifications.

FIG. 3 illustrates an example training data generation system.

FIG. 4 is a flowchart of an example method for using artificial intelligence for generating building design specifications.

FIG. 5 illustrates an example system that includes a translation layer for translating user building performance specification inputs into artificial intelligence model inputs.

FIG. 6 is a flowchart of an example method for an inference translation layer.

FIG. 7 illustrates an example system for generation of building designs using a model cascade.

FIG. 8 illustrates an example deep learning pipeline.

FIG. 9 is a flowchart of an example method for using a model cascade for generating building design information.

FIG. 10 illustrates an example system for a training data generator that generates training data for training artificial intelligence models to automatically generate building design specifications.

FIG. 11 is a flowchart of an example method for training data generation.

### DETAILED DESCRIPTION

This disclosure generally describes computer-implemented methods, software, and systems for a system for artificial intelligence in building construction.

### AI System for Automatic Generation of Design Specifications

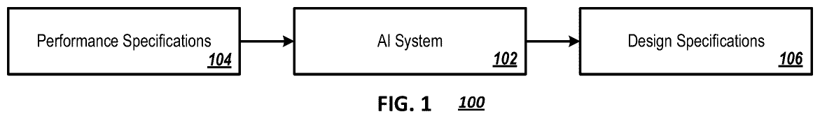

FIG. 1 illustrates an example system 100 for automatic generation of building design specifications. An AI system 102 can receive performance specifications 104 for a building project as input. The performance specifications 104 can be multi-modal, as described in more detail below, including image data and/or textual data, materials data, graph data, geospatial data, three-dimensional data, and other data sets. The AI system 102 can generate building design specifications 106 that match/satisfy the performance specifications 104 (if such designs are possible), by taking the input multi-modal specification data into account. The building design specifications 106 generated by the AI system 102 can include engineering designs for a building plan for the building project.

In further detail, the performance specifications 104 may include, for example, an allowable project budget, a number of buildings, a parcel of land, and a desired floor to area ratio. As other examples, the performance specifications 104 may include certain target environmental impacts for water use, electricity use, embodied carbon, etc. In some examples, the performance specifications 104 may specify building material type (e.g., concrete, mass timber, brick, stone, wood), number of floors, and/or regulatory compliance requirements. The performance specifications can also include structural metrics, plumbing and electrical constraints, risk metrics for hurricane, flood, fire or other hazards, or buildability metrics.

The AI system 102 may take as input specific values for each of these types of performance specifications. The performance specifications 104 may include a natural language description related to the aesthetics or performance of the desired building design. In some examples, the performance specifications 104 can include indications of preferences or priority information indicating that the user wants to maximize, minimize, or target a specific value for a performance specification. For example, the user may specify, in the performance specifications 104, a desire to prioritize minimizing a budget while maximizing a floor-to-area ratio for a three story building.

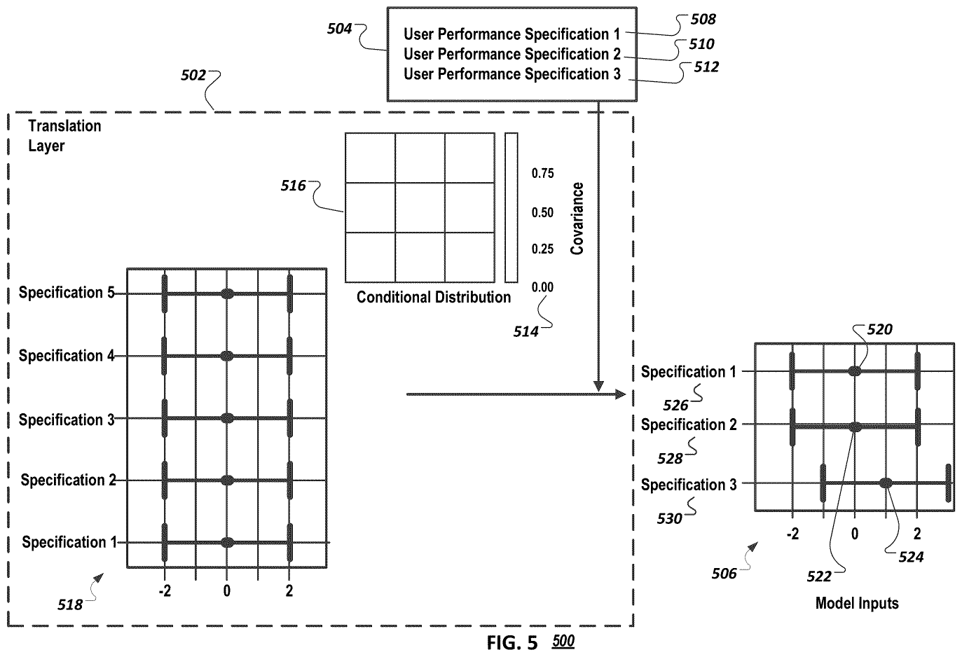

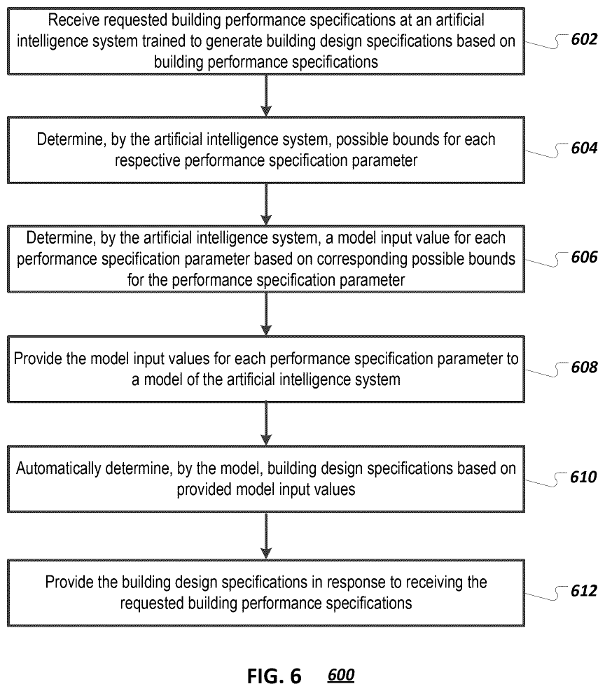

The performance specifications 104 may be provided in various formats, including text, numerical, image, vector image (e.g., SVG (Scalable Vector Graphics)), graph, and others. For example, the performance specifications 104 can include information that requests: (1) mimicking the design aesthetic within a given image; (2) staying within a given lot boundary specified as a list of parcel edges or vertices; (3) a number of buildings or floors to which to adhere; (4) a section of building code to follow; or (5) a connectivity graph where nodes denote buildings and edges denote accessibility between buildings. In some implementations, the AI system 102 uses or includes a translation layer that translates some performance specification inputs 104 into viable values within possible bounds for respective specifications, as described in more detail below with respect to FIGS. 5 and 6.

The building design specifications 106 may include a vector representation of an overall building shape (e.g., the building massing), a representation of the structural features of the building, a representation of a floorplate layout and floor plans of the building, a representation of the mechanical, electrical and plumbing features of the building, and a representation of the materials to be used in the building.

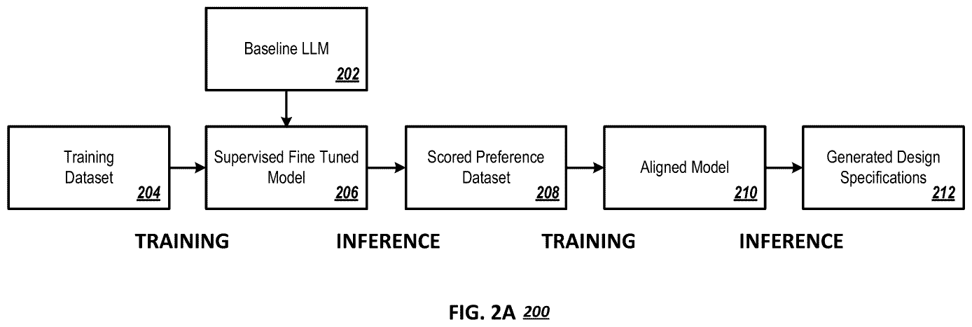

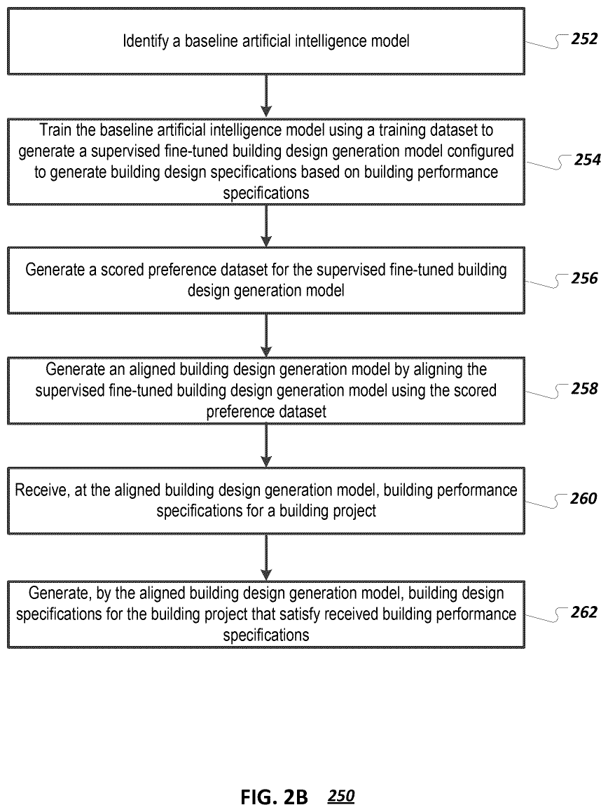

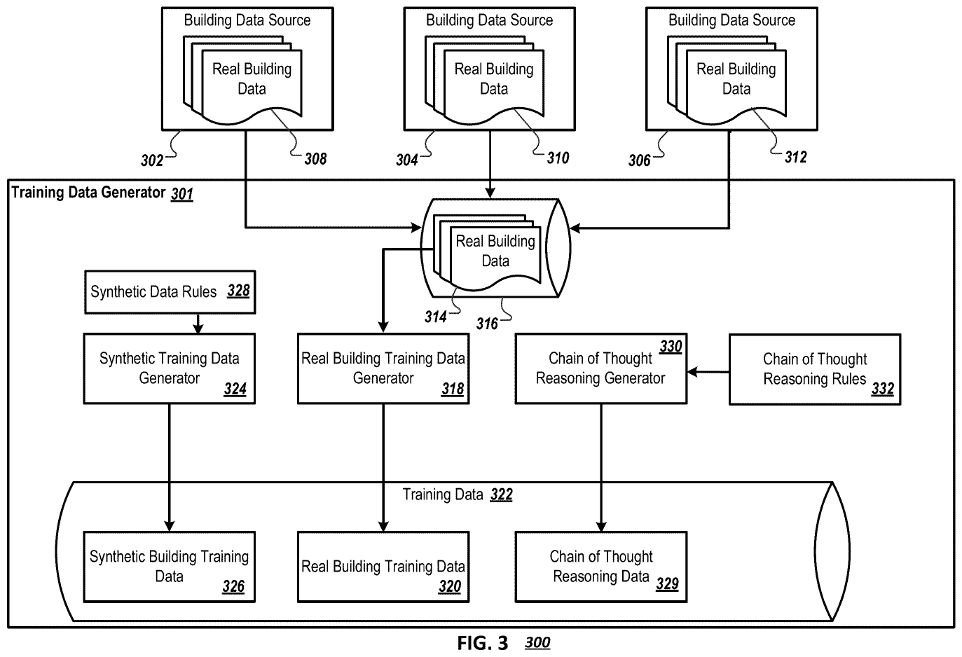

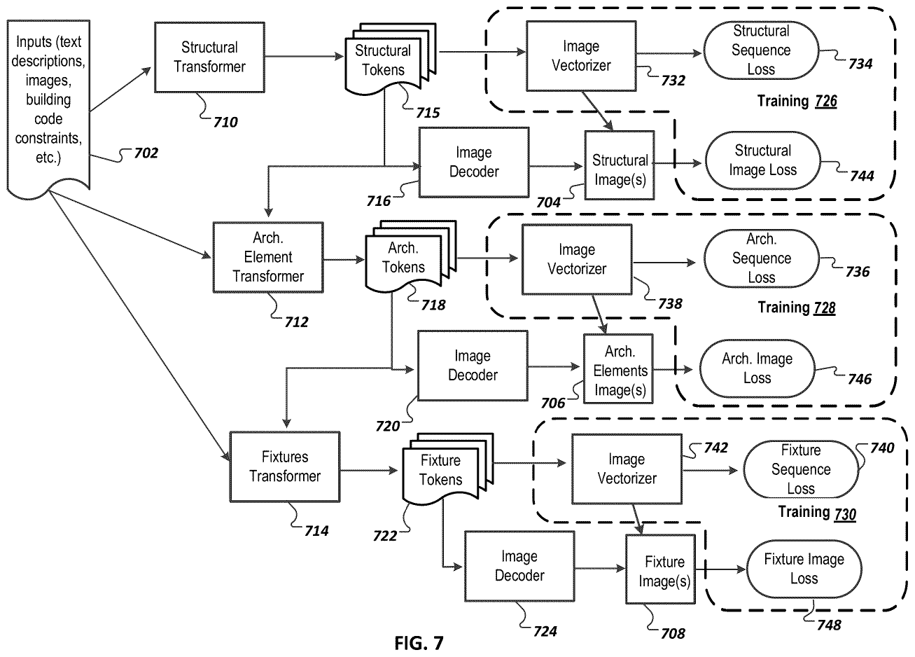

The AI system 102 may be a standalone AI system that develops different kinds of design specifications. As another example, the AI system 102 may be configured to generate one kind of design specifications and may be part of a system that includes other AI systems that generate other kinds of design specifications. For example, the AI system 102 may be included in a model cascade system that is described in more detail below with respect to FIGS. 7 to 11. The AI system 102 can be trained, as described in more detail below with respect to FIG. 3. Training the AI system 102 may be part of a training, tuning, and alignment process that is described in more detail below with respect to FIGS. 2A-2B.

FIG. 2A illustrates an example system 200 for training, tuning, and aligning a system for automatic generation of building design specifications. A baseline LLM (Large Language Model), or another type of AI model, can be trained using a training data set 204, to generate a supervised fine-tuned building design generation model 206 that is trained to generate building design specifications based on building performance specifications. The training dataset 204 can include real and/or synthetic data (e.g., for real or synthetically-designed buildings, respectively). The training dataset 204 can be designed to represent language for specifying performance specifications for building projects.

The baseline LLM 202 may be trained in a self-supervised manner by training on a next token prediction task using a corpus of real or synthetic data to learn the rules of building designs. Generation of the supervised fine-tuned building design generation model 206 can include, for example, pre-training the baseline LLM 202 on a large corpus of data (e.g., textual data) to improve general pattern recognition and natural language generation capabilities of the supervised fine-tuned building design generation model 206 as compared to the baseline LLM 202. In some examples, the baseline LLM 206 can be trained (e.g., using fine-tuning, low rank adaptation, pre-training, or other approaches) to predict design specifications of the buildings given certain performance specifications. In some implementations, the baseline LLM 202 may be trained to predict design specifications of synthetic buildings given fully or partially specified building designs.

In some examples, the supervised fine-tuned building design generation model 206 may be trained on other tasks besides design generation, such as geometric manipulations of designs (e.g., adding an extra floor, extending to a boundary, etc.). Such geometric manipulations can be considered related tasks to generating building designs and training the supervised fine-tuned building design generation model 206 on such tasks may improve the intelligence of the supervised fine-tuned building design generation model 206 for understanding the general and overall domain of building design. For example, the model can learn that extending an outer wall is limited by overall constraints or specified performance specifications.

After generation of the supervised fine-tuned building design generation model 206, a scored preference dataset 208 for the supervised fine-tuned building design generation model can be generated. An aligned building design generation model 210 can be generated by aligning the supervised fine-tuned building design generation model 206 using the scored preference dataset 208.

In further detail regarding model alignment, generating of the aligned building design generation model 210 can include using reinforcement learning by human feedback (RLHF), direct preference optimization (DPO), Group Relative Policy Optimization (GRPO), prospect theoretic optimization, or other alignment strategies. The scored preference dataset 208 can include a mix of generated, synthetic, and real datasets that are scored based on how closely those datasets match input performance specifications. In some cases, some preference scores may be based on human feedback. In some implementations, different approaches can be used for alignment by combining a DPO approach with other techniques (e.g., RLHF+DPO, Contrastive Learning+DPO, Supervised Fine-Tuning (SFT)+DPO+Chain-of-Thought (CoT) prompting/reasoning etc.).

In further detail regarding model training and alignment, a technique of RLTF (RL with Toolset Feedback) can be used. For example, a set of tools that are available for the AI model can be used at different stages of training to evaluate intermediate training results. The tool set can range, for example, from metric calculating classes to sophisticated analysis scores on intermediate model generations. Incorporating early feedback from the tool set during training can improve model alignment accuracy and speed. Early feedback can be particularly useful for a CoT training paradigm but is generic enough to be applied in any training pipeline.

In general, during alignment, generated designs can be evaluated and scored with a holistic approach that can include a range of evaluators assessing factors including, but not limited to, structural aspect, shape, form factor, practical use, utilization of space, lighting etc. Designs that are scored during alignment can be scored and used for model alignment to better align the model towards generating design specification respecting input performance specifications. In some alignment examples, alignment can include aligning the model for certain metrics or user specifications (e.g., scoring and aligning the model with respect to handling a specific user specification such as “prefer solar lighting”).

In further detail regarding chain of thought reasoning, in some cases, the training dataset 204 may be augmented with reasoning steps that provide suggested chains of thought reasoning for creating certain building designs given certain performance specifications. For example, the supervised fine-tuned building design generation model 206 may be generated by training the baseline model 202 to provide a chain of reasoning for proposed design specifications. For instance, the supervised fine-tuned building design generation model 206 may be prompted to explain why the proposed design specifications were chosen given the performance specifications. As another example, the supervised fine-tuned building design generation model 206 may be prompted to generate a reasoning for placing certain design elements in a design specification given existing design elements in the design specifications, current design specifications, and input performance specifications. As a particular example, the supervised fine-tuned building design generation model 206 can be prompted to provide a set of reasonings that explain why the model performed a next step of generating a massing given previous steps. The chain of thought reasoning can be provided, as part of a feedback loop, in the training dataset 204 during training.

Other training or model adaptations approaches can be used. For example, in some cases, a supervised fine tuning step may be skipped and the baseline LLM 202 may be trained directly using a reinforcement learning algorithm. As another example, low rank adaption approaches can be used to convert a larger model into a smaller model by reducing/shrinking parameters (e.g., so that the model can fit on smaller devices). As another example, different orders of SFT (Supervised Fine Tuning) and RL (Reinforcement Learning) can be applied to the model to equip the model with some domain knowledge with SFT and then honing the domain knowledge further with RL on a full domain or a specific sub-domain. Furthermore, an entire cycle of one or more SFT activities followed by one or more RL training activities can then be repeated for multiple domains/sub-domains.

The aligned building design generation model 210 can be used during inference. For example, building performance specifications for a building project can be received at the aligned building design generation model. The aligned building design generation model 210 can generate building design specifications 212 for the building project that satisfy received building performance specifications.

FIG. 2B is a flowchart of an example method 250 for generating an aligned artificial intelligence model for generating building design specifications.

At 252, a baseline artificial intelligence model is identified. The baseline artificial intelligence model may be a large language model or another type of model.

At 254, the baseline artificial intelligence model is trained using a training dataset to generate a supervised fine-tuned building design generation model configured to generate building design specifications based on building performance specifications. The training dataset can include data for existing (e.g., real) buildings and/or synthetically-generated training data.

In some examples training the baseline artificial intelligence model using the training dataset to generate the supervised fine-tuned building design generation model includes training the supervised fine-tuned building design generation model in a self-supervised manner on a next token prediction task to learn rules of building designs. In some examples, training the baseline artificial intelligence model using the training dataset to generate the supervised fine-tuned building design generation model comprises training the supervised fine-tuned building design generation model to predict design specifications of buildings based on received performance specifications. In some examples, generating the supervised fine-tuned building design generation model comprises training the supervised fine-tune building design generation model to perform tasks related to a building domain such as geometric manipulation of building designs to improve an understanding of the supervised fine-tuned building design generation model with respect to the building domain.

At 256, a scored preference dataset is generated for the supervised fine-tuned building design generation model.

At 258, an aligned building design generation model is generated by aligning the supervised fine-tuned building design generation model using the scored preference dataset. In some examples, aligning the supervised fine-tuned building design generation model includes using one or more of reinforcement learning by human feedback, direct preference optimization, or group relative policy optimization. In some examples, aligning the supervised fine-tuned building design generation model includes: prompting the supervised fine-tuned building design generation model to generate chain of thought explanations that explain why proposed design specifications were chosen for given performance specifications; and using the chain of thought explanations during the aligning.

At 260, building performance specifications for a building project are received at the aligned building design generation model.

At 262, the aligned building design generation model generates building design specifications for the building project that satisfy received building performance specifications.

FIG. 3 illustrates an example system 300 for a training data generator 301 that generates training data for training artificial intelligence models to automatically generate building design specifications. The training data generator 301 can identify real building data sources 302, 304, and 306 that can provide, for example, real building data sets 308, 310, or 312, respectively. The training data generator 301 can store received or obtained real building data 314 in a real building data repository 316. The real building data 314 can include information about 3D geometry of real buildings, for example. The real building data sources 302, 304, and 306 can provide point cloud data about real building geometry. As another example, the real building data sources 302, 304, and 306 can provide map data about real buildings.

A real building training data generator 318 can generate real building training data 320 from the real building data 314, for storage and use as part of training data 322. For example, the real building training data generator 318 can extract or generate, from the real building data 314, vector representations that represent shapes of buildings for which data is included in the real building data 314. For instance, the real building training data 320 can include real building data representations that can include vector information that describes a polygon that represents a particular building's shape. Performance specifications of the real buildings can be evaluated and the performance specifications can be stored in the real building training data 320 in association with design information of the real buildings.

As another example creation of training data 322, a synthetic training data generator 324 can generate synthetic training data 326, based, for example, on synthetic data rules 328. The synthetic training data generator 324 can create building design specifications based on building shapes that include connected rectangular prisms that are connected while satisfying the synthetic data rules 328 such as smaller rectangles being able to be stacked on larger rectangles but not vice versa.

Building design information included in the synthetic training data 326 may include information for designs that are fully or partially specified (e.g., the synthetic training data 326 may include, for a design, detailed information for all phases of building construction, or, as another example, design information just for an overall massing shape (or any other examples including an amount of design information between those two examples). Performance specifications of the synthetic building designs can be evaluated and the performance specifications can be stored in the synthetic training data 326 in association with design information of the synthetic buildings. The synthetic data rules 328 can include different sets of rules and the synthetic training data generator 324 can create different sets of synthetic training data using different sets of rules.

In some cases, the training data 322 includes chain of thought reasoning data 329, as described above. In some cases, a chain of thought reasoning data generator 330 can generate chain of thought reasoning data 329 based on chain of thought reasoning rules 330. In some examples and as described above, in some cases a model being trained (or another model) can be prompted to generate training data (and accordingly, the chain of thought reasoning data 329 may be model-generated data).

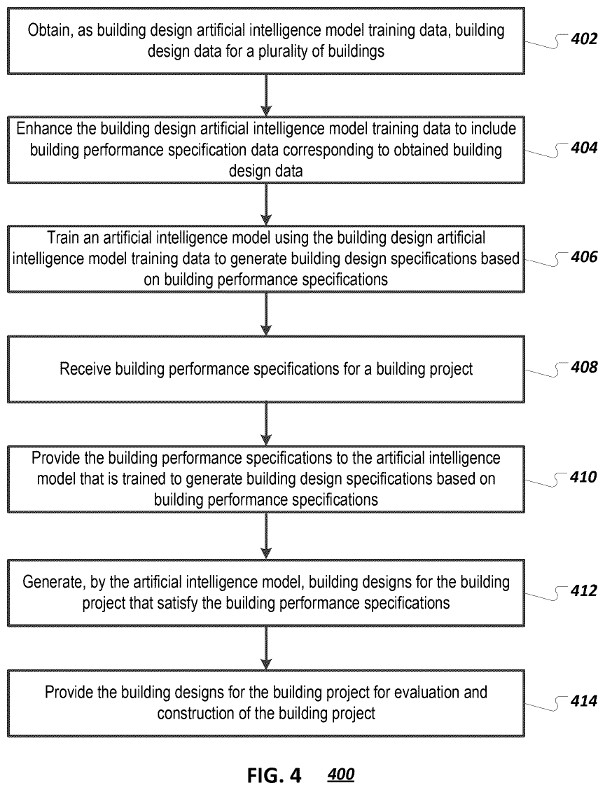

FIG. 4 is a flowchart of an example method 400 for using artificial intelligence for generating building design specifications.

At 402, building design data for a plurality of buildings is obtained as building design artificial intelligence model training data. For example, building design data for existing buildings can be obtained. As another example, synthetic data for synthetically-designed buildings can be generated. The synthetic data can be generated based on a set of rules that includes rules for how buildings can be composed.

At 404, the building design artificial intelligence model training data is enhanced to include building performance specification data corresponding to obtained building design data. For example, building performance specifications can be determined for obtained building design data and associated, in the building design artificial intelligence model training data, with corresponding building design information. In some implementations, the artificial intelligence model is trained to generate one kind of building design information selected from at least structural, architectural, and fixtures-related designs. In some examples, the artificial intelligence model is included with other artificial intelligence models in a model cascade in which outputs of some artificial intelligence models are provided as inputs to other artificial intelligence models. The model cascade can include different models for structural, architectural elements, and fixtures-related designs, for example.

At 406, an artificial intelligence model is trained using the building design artificial intelligence model training data to generate building design specifications based on building performance specifications. In some implementations, the artificial intelligence model is trained to generate different kinds of building designs, including structural, architectural, and fixtures-related designs.

At 408, building performance specifications are received for a building project. Received performance specifications can include multi-modal information comprising at least textual and image inputs.

At 410, the building performance specifications are provided to the artificial intelligence model that is trained to generate building design specifications based on building performance specifications. In some examples, a translation layer may translate performance specifications before performance specification information is provided to the artificial intelligence model. For instance, in some implementations, the method includes: determining possible bounds for a first performance specification parameter included in received performance specifications; determining that a received value for the first performance specification parameter is outside of the possible bounds for the first performance specification parameter; adjusting the received value for the first performance specification parameter to be within the possible bounds for the first performance specification parameter; and providing an adjusted value for the first performance specification parameter to the artificial intelligence model.

At 412, the artificial intelligence model generates building designs for the building project that satisfy the building performance specifications.

At 414, the building designs are provided for the building project for evaluation and construction of the building project.

### Inference Translation Layer

FIG. 5 illustrates an example system 500 that includes a translation layer 502 for translating user building performance specification inputs 504 into artificial intelligence model inputs 506. The artificial intelligence model inputs 506 can be provided to an artificial intelligence model that is trained to generate building designs that are designed to meet the user building performance specification inputs 504.

When a user provides the building performance specification inputs 504, the user may, for some specifications, know and provide a specific value for a given specification. For example, an instance of the user performance specification 508 may specify that the user desires a building with three floors. In some cases, the user may not be completely aware or confident that certain performance specifications are possible in combination with other performance specifications, or the user may not know, in general, what target performance specifications are possible for some types of specifications. In some cases, the user may specify a list of important performance specifications (which may include relative importance) and/or a desire to maximize, minimize, or target a specific value for each specification. For instance, an instance of the user performance specification 510 may specify that the user desires “maximum solar light.” As another example, a third user performance specification may specify that the user desires a “maximum floor-to-area ratio.”

The translation layer 502 can translate maximum, minimum, or target user input specification values into a specific set of performance specifications based on what the translation layer 502 determines are viable performance targets. The translation layer 502 can serve as a layer between what users might specify and what the artificial intelligence model might require as input for building design generation.

The translation layer 502 may use statistical metrics, such as conditional probability distributions or Mahalanobis distances to determine a viable set of performance metrics given a user specification. In order to determine viability, the translation layer 502 may compute statistical distance metrics (e.g., Mahalanobis distance) between the user's performance specifications 504 and the training data statistics. If a distance for a user performance metric is greater than a threshold, the translation layer 502 may determine that a user performance specification is not viable. If the distance is less than the threshold, the translation layer 502 may determine that the user performance specification is viable.

The translation layer 502 may start with a performance specification deemed to be most important and specify a target value based on the distribution of values seen in the training data conditioned on the constraints for this case (e.g. the parcel boundaries). For example, if the user specifies that they want to maximize floor to area ratio and that this is the most important performance specification, then the system may start by setting a target value for floor to area ratio based on the distribution of floor to area ratios in the training data conditioned on this parcel size. Then, if the user also has specified that they want to minimize construction cost, then the system may determine a viable target value for construction cost conditioned both on the original constraint of parcel size and on the target value for floor to area ratio. This same process could be followed for third, fourth, fifth, etc. target specifications.

In some cases, the bounds can be communicated to the user, and the user can select performance specification values within those bounds. In other cases, the translation layer 502 may automatically select a value for a performance criteria that is within allowed bounds. In some cases, the translation layer 502 communicates that an initial user value is outside of allowed bounds (and a new value within allowed bounds can be received from the user or can be selected by the translation layer 502).

After performance specification validation and possible adjustment, the artificial intelligence model inputs 506 can include respective values 520, 522, and 524 for model parameters 526, 528, and 530 that correspond to the user performance specifications 508, 510, and 512, respectively.

FIG. 6 is a flowchart of an example method 600 for an inference translation layer.

At 602, requested building performance specifications are received at an artificial intelligence system trained to generate building design specifications based on building performance specifications. Each requested building performance specification corresponds to a respective performance specification parameter. In some examples, the requested building performance specifications include at least a first building performance specification that requests a maximum or minimum value for a first performance specification parameter. In some examples, the requested building performance specifications include at least a second building performance specification that requests an explicit value for a second performance specification parameter.

In some examples, the requested building performance specifications include different relative priorities of different performance specifications. For example, a priority of a first performance specification of “maximizing solar light” may be higher than a priority for a second performance specification of “maximizing a floor-to-area ratio.”

In some examples the requested building performance specifications include at least two related building performance specifications that each relate at least in part to a first parameter. For example, a first performance specification may be “maximize floor-to-area ratio” and a second performance specification may be “use three floors” (e.g., where both parameters relate, at least in part, to a number of floors).

At 604, the artificial intelligence system determines possible bounds for each respective performance specification parameter. In examples where the first building performance specification requests a maximum value for the first performance specification parameter, determining the possible bounds for the first performance specification parameter can include determining an upper possible bound for the first performance specification parameter. In examples where the first building performance specification requests a minimum value for the first performance specification parameter, determining the possible bounds for the first performance specification parameter can include determining a lower possible bound for the first performance specification parameter.

At 606, the artificial intelligence system determines a model input value for each performance specification parameter based on corresponding possible bounds for the performance specification parameter. In examples where the first building performance specification requests a maximum or minimum value for the first performance specification parameter, determining the model input value for the first performance specification parameter can include automatically determining the upper or lower possible bound of the first performance specification parameter as the model input value for the first performance specification parameter. In some examples, determining the upper or lower possible bound of the first performance specification parameter as the model input value for the first performance specification parameter can include: providing, in response to receiving the requested building performance specifications, the upper or lower possible bound as a suggested model input value for the first performance specification parameter; receiving a confirmation of using the upper or lower possible bound as the model input value; and determining the upper or lower possible bound as the model input value for the first performance specification parameter in response to the confirmation. In some examples, determining the model input value for the first performance specification parameter can include: providing, in response to receiving the requested building performance specifications, the upper or lower possible bound as a suggested model input value for the first performance specification parameter; receiving, as a modified model input value, a modification of the suggested model input value; determining that the modified model input value is within the possible bounds of the first performance specification parameter; and determining the modified model input value as the model input value for the first performance specification parameter.

In examples where the requested building performance specifications include at least a second building performance specification that requests an explicit value for a second performance specification parameter, determining the model input value for the second performance specification parameter can include: determining that the explicit value is within the possible bounds of the second performance specification parameter; and automatically selecting the explicit value as the model input value for the second performance specification parameter in response to determining that the explicit value is within the possible bounds of the second performance specification parameter. In some examples, determining the model input value for the second performance specification parameter includes: determining that the explicit value is not within the possible bounds of the second performance specification parameter; providing possible bounds information for the second performance specification parameter in response to receiving the requested building performance specifications; receiving a new explicit value for the second performance specification parameter; determining that the new explicit value is within the possible bounds of the second performance specification parameter; and selecting the new explicit value as the model input value for the second performance specification parameter in response to determining that the new explicit value is within the possible bounds of the second performance specification parameter.

In examples where the requested building performance specifications include different relative priorities of different performance specifications (e.g., in examples where the requested building performance specifications include at least two related specifications (e.g., both floor-to-area ratio and number of floors)), determining a model input value for a parameter can include determining that the model input value for the parameter satisfies each of the related building performance specifications. The model can determine how best to satisfy both performance specifications (e.g., maximizing a floor-to-area ratio for designs that include three floors).

In examples where the requested building performance specifications include different relative priorities of different performance specifications (where a priority of “maximizing solar light” is higher than priority for a “maximizing a floor-to-area ratio”), the model may prioritize determination of model input values for performance specifications with higher relative priorities over model input values for performance specifications with lower relative priorities. For example, the model may determine design specifications that result in a higher amount of solar light even at the expense of a design that has a lower floor-to-area ratio than an unchosen design that has a higher floor-to-area ratio but less solar light.

The model input value for a first user specification parameter can be based on training data for the first user specification parameter. For example, constraints of the building project can be identified (e.g., a parcel size). Filtered training data can be generated by filtering the training data based on the constraints of the building project and the first user specification parameter. The model input value for the first user specification parameter can be determined based on a distribution of values for the first user specification parameter in the filtered training data. When multiple user performance specifications are received that have different priorities, a model input value for a second user specification parameter that has a lower importance value than the first user specification parameter can be determined based on training data for the second user specification parameter and a previously-determined model input value for the first user specification parameter.

At 608, the model input values for each performance specification parameter are provided to a model of the artificial intelligence system.

At 610, the model automatically determines building design specifications based on provided model input values.

At 612, the building design specifications are provided in response to receiving the requested building performance specifications. For example, the building design specifications can be provided to a user or to a system. An acceptance of the building design specifications can be received (e.g., from a user) and building plans can be generated based on the building design specifications in response to receiving the acceptance of the building design specifications.

### Cascading Models System

FIG. 7 illustrates an example system 700 for generation of building designs using a model cascade. The system 700 can be used to generate architectural diagrams, such as floor plans and/or other drawings. Generating architectural diagrams and drawings such as floor plans traditionally is a labor-intensive process requiring the effort of human experts at various stages. Furthermore, existing systems that may employ some automation generally rely on rule-based or heuristic approaches that are brittle and hard to generalize to new applications. For example, a rule-based system developed to produce high-quality commercial office floor plans that meet certain constraints for size, cost, location, etc. will typically fail if asked to generate floor plans for a single-family home with substantially different constraints. As another example, a system designed for residential drawings generally cannot respond successfully to requests related to commercial buildings.

The system 700, in contrast, can provide flexible automation of building design generation using flexible deep learning techniques. The system 700 can use non-rule-based generative design systems that are capable of generalizing successfully to a wide range of design constraints and producing high-quality compromises in cases where outright success is impossible (e.g., because there are conflicting constraints that are impossible to satisfy simultaneously). The system 700 orchestrates multiple multimodal transformer-based deep learning models (or other types of models) to produce detailed, high-quality floor plans that respect a wide range of possible constraints provided via multimodal (e.g., text, image) inputs 702. The system 700 can produce a series of images that describe floor plans and other designs, including structural images 704, architectural elements images 706, and fixture images 708. Additionally, the system 700 can generate other outputs, such as Industry Foundation Classes (IFC) files that can be read into a wide range of existing CAD (Computer Aided Design) and BIM (Building Information Management) packages.

The system 700 is structured as a model cascade, and processing can proceed in stages from basic structural design to finer-grained design details. For example, the system 700 includes multiple models, where each model is specialized for a particular task. For instance, the system 700 includes a structural transformer 710 for generating structural elements, an architectural elements transformer 712 for generating architectural elements, and a fixtures transformer 714 for generating fixture-based elements. In other implementations, additional or fewer transformers may be used. In some cases, some or all of the models used in the system 700 can be the AI system 102 described above with respect to FIG. 1.

Each of the structural transformer 710, the architectural elements transformer 712, and the fixtures transformer 714 can be provided the inputs 702 that include relevant constraints passed in by the user (e.g., the inputs 702 can provide a detailed description of a final floor plan or other design). Additionally, and as described in more detail below, transformers in the cascade after a first transformer (e.g., the architectural elements transformer 712 and the fixtures transformer 714) can be provided with the output of previous modeling stage(s). Transformers in the cascade can be trained, as described below. In an inference phase, design artifacts can be generated and provided to the user.

The inputs 702, as mentioned, can be multimodal inputs that can include text and image inputs. In a training phase, the inputs 702 can include training inputs. In an inference phase, the inputs 702 can be user-provided inputs.

Text inputs can include, for example, free-form natural language descriptions of a desired output, such as “a two-bedroom, two-bathroom apartment with an open floor plan and a large patio. ” As another example, text inputs can be free-form editing instructions for modifying another part of the design or another input (e.g., “convert part of the depicted living room into a small powder room”). Textual inputs can also include numerical constraints on prespecified parameters, such as constraints for construction cost, sustainability ratings, usable floor area, etc., or constraints corresponding to building code constraints.

Image inputs included in the inputs 702 can include various types of images that can impose constraints on the building design. For example, the inputs 702 can include one or more of: image(s) that might influence a generated floor plan; image(s) showing outer walls (e.g., a footprint) providing boundaries to be filled in with a complete design; image(s) showing a partial floor plan with one or more portions missing or masked out (e.g., where the portions can be “inpainted” by a model of the cascade); image(s) showing other floor plans the user wants to adapt a style from (e.g., to apply similar furnishings, fixtures, etc.); or image(s) showing a complete floor plan that the user wishes to modify via natural language instructions.

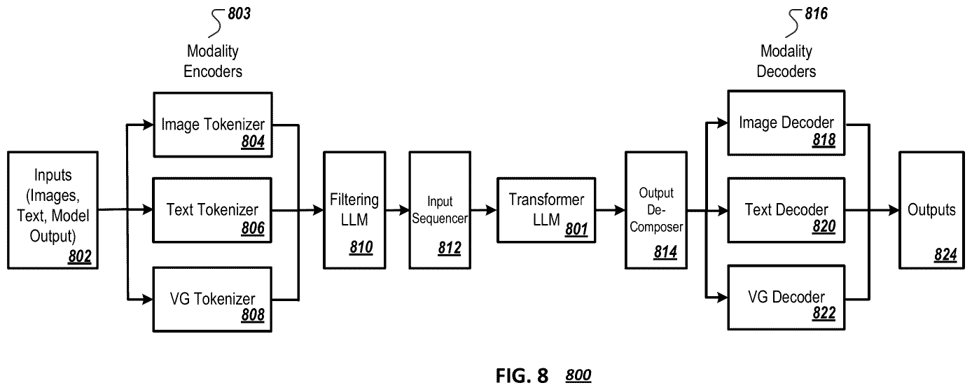

The structural transformer 710 is trained to produce design data representing the outer walls (e.g., footprint) of a floor plan. The structural transformer 710 can, for example, generate structural tokens 715 that represent the structural design. The structural tokens 715 can be provided to an image decoder 716 that can convert the structural tokens 715 into the structural images 704. The structural tokens 715 may be provided to other decoders, as described below. The structural transformer 710 and associated components can utilize a pipeline/structure described in more detail below with respect to FIG. 8. FIG. 8 also illustrates a same pipeline/structure that can be used for the architectural elements transformer 712 and the fixtures transformer 714.

FIG. 8 illustrates an example deep learning pipeline 800. The deep learning pipeline 800 involves a transformer LLM 801 (which can be, for example, the structural transformer 710, the architectural elements transformer 712, the fixtures transformer 714, or some other transformer LLM). The pipeline 800 can receive inputs 802 (which can be, for example, the inputs 702 and possibly output data from another model, such as a previous model in a model cascade such as shown in FIG. 7).

Particular portions of the inputs 802 can be processed by corresponding modality-specific encoders 803 (e.g., tokenizers), depending on a corresponding modality. For example, image-based inputs can be processed by an image tokenizer 804 (e.g., vision transformer) which can produce image encodings (e.g., image tokens), text-based inputs can be processed by a text tokenizer 806 which can produce text encodings (e.g., text tokens), and vector graphic (VG)-based inputs can be processed by a vector graphics tokenizer 808 which can produce VG encodings (e.g., VG tokens).

Respective tokens generated by the modality-specific encoders 803 can be provided to a filtering LLM 810 (or another type of filtering component). With respect to the model cascade of the system 700, not all user inputs (e.g., not all of the inputs 702) may be relevant for a given stage/given transformer. Accordingly, the filtering LLM 810 can filter received tokens according to the type of the transformer LLM 801.

For example, the user may provide an image of an existing floor plan whose style the user wishes to adapt for a current floor plan (e.g., the user may also provide instructions that specify a desire to adapt the style of the existing floor plan). The style of the existing floor plan may only be relevant in this example for the fixtures transformer 714 (and not for the structural transformer 710 or the architectural elements transformer 712). Accordingly, when the transformer LLM 801 is the fixtures transformer 714, the filtering LLM 810 can provide image tokens relevant to the existing floor plan and corresponding text tokens describing instructions to adapt the style of the existing floor plan to a next component of the pipeline 800 (e.g., an input sequencer 812). When the transformer LLM 801 is another type of transformer (e.g., the structural transformer 710 or the architectural elements transformer 712) the filtering LLM 810 can filter out the tokens related to the existing floor plan and the requested adaptation so that the transformer LLM 801 does not receive such tokens.

The filtering LLM 810 is trained to determine which tokens are relevant to which transformers. Although the filtering LLM 810 is shown as appearing in the pipeline 800 after the modality-specific encoders 803, in some implementations, the filtering LLM 810 may exist at least in part before the modality-specific encoders 803. For example, the filtering LLM 810 may be trained to process natural text inputs (e.g., user requests or descriptions) and determine which transformers are relevant for processing those text inputs and any corresponding other inputs (e.g., accompany images that relate to the requests or descriptions). Relevant inputs may then be processed by corresponding modality-specific encoders 803.

The tokens relevant to the transformer LLM 801 can be provided to the input sequencer 812. The input sequencer 812 can concatenate the relevant tokens (e.g., relevant image, text, and VG tokens) into a single sequence of input tokens. The input sequencer 812 can, for example, project encoded image token sequences (if any) into a space of a same dimension as relevant text sequences. The single sequence of input tokens generated by the input sequencer 812 can be provided to the transformer LLM 801.

The transformer LLM 801 can generate a sequence of output tokens. As mentioned, the transformer LLM 801 may be the structural transformer 710, the architectural elements transformer 712, or the fixtures transformer 714 and the sequence of output tokens may be output tokens that describe structural, architectural, or fixture design elements, respectively. The sequence of output tokens generated by the transformer LLM 801 can be provided to an output decomposer 814.

The output decomposer 814 can decompose the sequence of output tokens into constituent modalities (e.g., image output token, text output token and VG output token subsequences) and provide decomposed subsequences to different modality-specific decoders 816 (e.g., an image decoder 818, a text decoder 820, or a VG decoder 822), respectively. Each of the modality-specific decoders 816 can generate a respective output (e.g., image, text, vector graphics) for inclusion in pipeline outputs 824. During inference, the pipeline outputs 824 can be outputs provided to a user. During training, the pipeline outputs 824 can be used for training or model tuning purposes, for example. During training or inference, some of the pipeline outputs 824 (and/or corresponding output tokens generated by the transformer LLM 801) may be provided as input for a next model in a model cascade.

For example and referring again to FIG. 7, the structural tokens 715 can be provided, along with the inputs 702, to the architectural elements transformer 712. The architectural elements transformer 712 can generate architectural tokens 718 that can describe architectural items such as interior walls (e.g., non-load-bearing walls), doors, and windows. Providing both the structural tokens 715 and the inputs 702 provides more information to the architectural elements transformer 712 for learning and output generation as compared to providing just the inputs 702, which can enable the architectural elements transformer 712 to generate the architectural tokens 718 as a higher quality output as compared to output generated just on user-provided inputs. The architectural tokens 718 can be provided to an image decoder 720 that can convert the architectural tokens 718 into the architectural element images 706. The architectural tokens 718 may be provided to other decoders, as described above for FIG. 8.

Processing can continue in a similar fashion for the model cascade, with the architectural tokens 718 being provided, along with the inputs 702 (and possibly along with the structural tokens 715), to the fixtures transformer 714. The fixtures transformer 714 can generate fixture tokens 722 that can describe fixture items such as fixtures, furnishings, and equipment (e.g., cabinetry, toilets, showers, shelving, etc.). Providing both the architectural tokens 718 and the inputs 702 provides more information to the fixtures transformer 714 for learning and output generation as compared to providing just the inputs 702. The fixture tokens 722 can be provided to an image decoder 724 that can convert the fixture tokens 722 into the fixture images 708. The fixture tokens 722 may be provided to other decoders, as described above for FIG. 8.

Output tokens and output images generated by respective transformers or pipelines can also be used during training. For example, the structural tokens 715 and the structural images 704 that are generated during training can be used in a training phase 726 for the structural transformer 710. Similarly, the architectural tokens 718 and the architectural elements images 706 can be used in a training phase 728 for the architectural elements transformer 712 and the fixture tokens 722 and the fixture images 708 can be used in a training phase 730 for the fixtures transformer 714.

For example, during training, the inputs 702 can be mapped to ground truth/target training images and other ground truth output. For instance, in some cases a ground truth vectorization may exist, if some subsets of training data are synthetically generated. In such examples, during the training phase 726, the structural tokens 715 of an image modality generated during a training run can be provided to an image vectorizer 732, which can produce output vectorization data. The output vectorization data can be compared to the ground-truth vectorization data to generate a structural sequence loss 734, which can be backpropagated in the system 700 to update weights of the structural transformer 710, for example. Similar backpropagation can occur for the architectural elements transformer 712 and/or the fixtures transformer 714 based on an architectural sequence loss 736 computed based on outputs from an image vectorizer 738 during the training phase 728 or based on a fixture sequence loss 740 computed based on outputs from an image vectorizer 742 during the training phase 730, respectively.

As another example, training inputs can correspond to ground truth/target image data. In such examples, an output image can be compared against a target image to produce image loss data which can be backpropagated through the system 700. For instance, during the training phase 726, the structural images 704 can be compared to corresponding target images to generate structural image loss data 744, which can be used to update the structural transformer 710. As another example, during the training phase 728, the architectural element images 706 can be compared to corresponding target images to generate architectural image loss data 746, which can be used to update the architectural elements transformer 712. Similarly, during the training phase 730, the fixture images 708 can be compared to corresponding target images to generate fixture image loss data 748, which can be used to update the fixtures transformer 714. Respective sets of image loss data can be computed, for example, using computer vision loss functions (e.g., pixel-wise mean squared error between two images, perceptual loss, etc.).

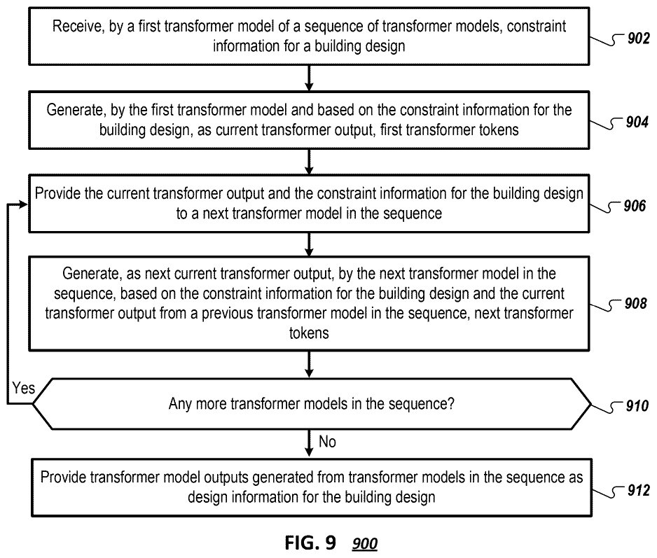

FIG. 9 is a flowchart of an example method 900 for using a model cascade for generating building design information.

At 902, a first a transformer model of a sequence of transformer models receives constraint information for a building design. Each model of the sequence can be configured to generate transformer tokens comprising building design information. The sequence of transformer models can include at least a structural transformer model configured to generate structural design information, an architectural element transformer model configured to generate interior architectural design information, and a fixtures transformer model configured to generate fixture design information for a design. In some implementations, the first transformer model is the structural transformer model, a second transformer model is the architectural elements transformer model, and a third transformer model is the fixtures transformer model. The constraint information can include at least one of textual constraint information or one or more images. The building design information generated by the sequence of transformer models can include floor plan design information and/or other design specifications.

At 904, the first transformer model generates, as current transformer output and based on the constraint information for the building design, first transformer tokens.

Transformer model output can be chained by providing transformer output from earlier models in the sequence as inputs to later transformer models in the sequence. In some implementations, the constraint information can be filtered, using a filtering model, for a given transformer model of the sequence before constraint information is provided to the given transformer model. A set of modality-specific encoders can encode inputs received at a given transformer model and encoded information can be provided to the transformer model. The set of modality-specific encoders can include an image tokenizer, a text tokenizer, and a vector graphics tokenizer, among others. In some implementations, inputs for a given transformer model are combined into a single sequence before the inputs are passed to the given transformer model.

At 906, for example, the current transformer model output (e.g., from the first transformer model) and the constraint information for the building design can be provided to a next transformer model in the sequence (e.g., a second transformer model).

At 908, the next transformer model in the sequence generates, as next current transformer output, based on the constraint information for the building design and the current transformer model output, next transformer tokens. The chaining of transformer model output can be repeated for one or more other transformer models.

At 910, for example, a determination can be made as to whether there are any more transformer models in the sequence.

Steps 906 (and in turn step 908) can be repeated in response to determining that there is at least a next transformer model (e.g., a third transformer model) in the sequence. For example, at 906, the current transformer model output generated by the second transformer model can be provided, along with the constraint information for the building design, to the third transformer model. In this example, at 908, the third transformer model can generate, as next current transformer output, based on the constraint information for the building design and the current transformer model output received from the second model, next transformer tokens.

At 912, in response to determining at step 910 that there are no more transformer models in the sequence, transformer model outputs generated from transformer models in the sequence can be provided as design information for the building design. A set of modality decoders can decode outputs generated by a given transformer model into, for example, respective text, image, or other types of output. The set of modality-specific decoders can include an image decoder, a text decoder, and a vector graphics decoder. The image decoder, the text decoder, and the vector graphics decoder can be respectively configured to generate an image, text, or vector graphics based on respective modality-specific transformer tokens of a given transformer.

In an inference phase, image or text outputs can be provided to a user. In a training phase, for a given transformer, outputs generated by the set of modality-specific decoders can be compared to one or more of the constraint information or ground truth data to generate at least one training signal that is provided to the given transformer to train or update the given transformer. As another example, in the training phase, a set of training images can be identified and provided along with a set of prompts to a large language model to request the large language model to generate, as further training data, natural language descriptions of the training images. The training images can also be provided the training images to an image vectorization model to request the image vectorization model to generate, as still further training data, vector graphic representations of the training images. Other training data generation examples can include performing computer vision techniques on the training images to extract footprints from the training images and randomly occluding portions of the training images to generate multiple masked versions of each training image.

### Training Data Generation for a Model Cascade

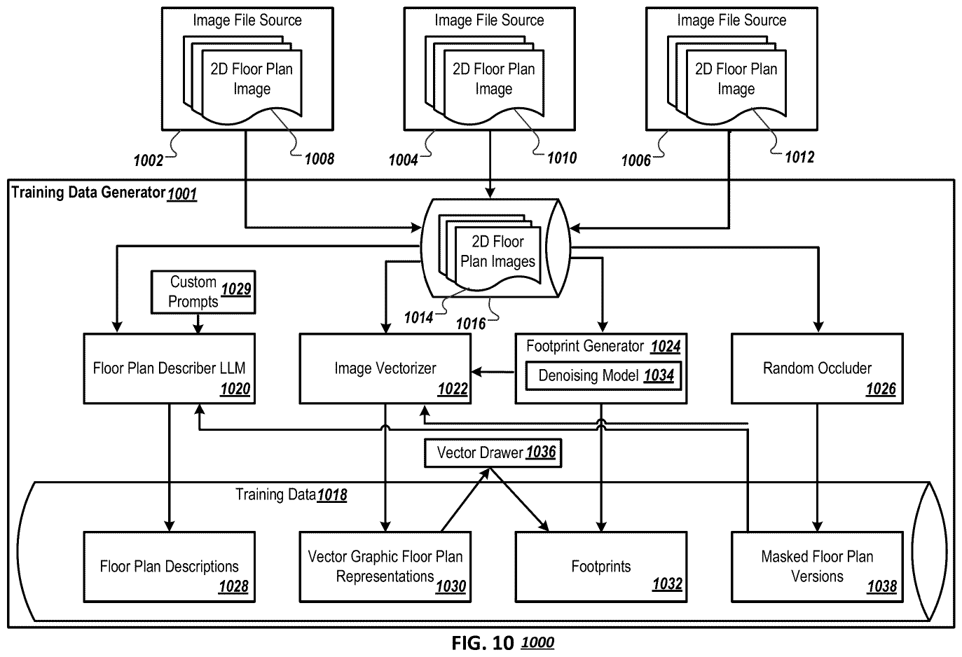

FIG. 10 illustrates an example system 1000 for a training data generator 1001 that generates training data for training artificial intelligence models to automatically generate building design specifications. Training a transformer-based system to convert multimodal input constraints into high-quality floor plans can require a large, varied training dataset that includes the same kinds of constraints that might be expected to be provided as inputs during inference. Training data requirements can include, for example: 1) a substantial number of 2D (two-dimensional) floor plan images; 2) natural language descriptions of the floor plans; 3) text-based vector graphics specifications (e.g., parameters to a series of drawing operations that can be used to deterministically reconstruct floor plans with high accuracy for use in model feedback loops); 4) footprint images that include only the outer walls of the floor plans; and 5) masked images where parts of the floor plan images are occluded, and two or more versions of each floor plan, where a specific visual difference is introduced in one version (e.g., by adding a bedroom, expanding a living room, etc.), where the floorplan images, text descriptions and vector graphic specifications all reflect the change. Such combinations of data sets generally do not exist at a scale sufficient for training a flexible AI model for generating building design specifications based on a flexible combination of performance specification inputs.

The training data generator 1001 can obtain certain data, such as floor plan images, and fill out other training data portions automatically. For example, the training data generator 1001 can generate natural language descriptions of floor plans or footprints (e.g., outer walls) of floor plans. Accordingly, the training data generator 1001 can create a harmonized training data set.

In further detail, to generate training data at a sufficient scale, the training data generator 1001 can identify image file sources 1002, 1004, and 1006 that can provide, for example, instances 1008, 1010, or 1012 of 2D floor plan images or other images, respectively. The training data generator 1001 can store received or obtained image files 1014 in an image file repository 1016. The obtained image files 1014 can be 2D floor plan or other images for which an entity associated with the training data generator 1001 has sufficient access rights. The image file sources 1002, 1004, and 1006 can be a combination of public and/or third party sources, where the third party sources have provided access rights to the training data generator 1001 to image files owned by the third party sources. The training data generator 1001 can obtain or filter images that are of at least a threshold quality, for example.

The training data generator 1001 can generate training data 1018 by providing some or all of the obtained image files 1014 to each of a floor plan describer LLM 1020, an image vectorizer 1022, a footprint generator 1024, and a random occluder 1026. The training data generator 1001 can include other components or engines that create training data based on 2D image files and/or can include components that create training data based on other types of inputs.

The floor plan describer LLM 1020 can generate different floor plan descriptions 1028 for each of different floor plan images. The training data generator 1001 can provide, for example, custom prompts 1029 to the floor plan describer LLM 1020 that instruct the floor plan describer LLM 1020 to generate different kinds of descriptions of the floor plans displayed in the floor plan images. The image vectorizer 1022 can be or include an image vectorization model that is trained to generate vector graphic representations 1030 of floor plan or other images.

The footprint generator 1024 can generate footprints 1032 that are images of floor plans that include just the outer walls of the floor plans. For example, the footprint generator 1024 can use computer vision techniques to generate the footprints 1032 from 2D floor plan images, for example. For instance, the footprint generator 1024 can apply pretrained segmentation models to a 2D floor plan image and select a most inclusive pixel mask produced from the segmenting. As another example, the footprint generator 1024 can generate a pixel mask using contour detection processing. The pixel mask obtained using segmenting or contour detection can be provided to a denoising model 1034 for noise reduction. The noise-reduced pixel mask can be provided to the image vectorizer 1022 to produce a vector graphic representation of the footprint, which can be provided to a vector drawer 1036 that can draw a clean version of the footprints for storage and use as the footprints 1032.

The random occluder 1026 can create other 2D floor plan images (e.g., masked floor plan versions 1038) by randomly occluding parts of the obtained image files 1014 to generate multiple masked versions of each obtained image. The masked floor plan versions 1038 can, in turn, be provided to the floor plan describer LLM 1020 and/or the image vectorizer 1022 to create floor plan descriptions or vector graphic representations of those floor plan image versions, respectively.

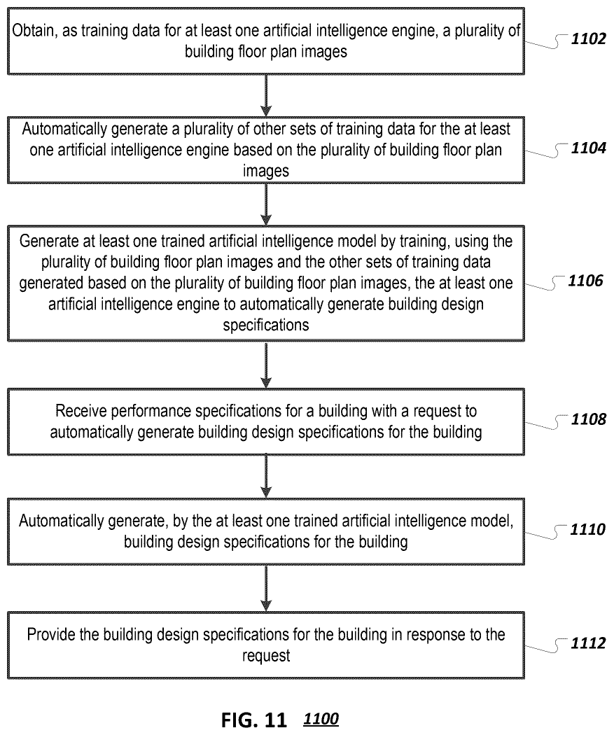

FIG. 11 is a flowchart of an example method 1100 for training data generation.

At 1102, a plurality of building floor plan images is obtained as training data for at least one artificial intelligence engine.

At 1104, a plurality of other sets of training data is automatically generated for the at least one artificial intelligence engine based on the plurality of building floor plan images. In some implementations, automatically generating the plurality of other sets of training data for the at least one artificial intelligence engine based on the plurality of building floor plan images includes: providing first building floor plan images and a prompt to a pretrained model trained to generate natural language descriptions from building floor plan images; receiving natural language descriptions of the first building floor plan images from the pretrained model; and including the natural language descriptions in the other sets of training data in association with corresponding first building floor plan images.

As another example, automatically generating the plurality of other sets of training data for the at least one artificial intelligence engine based on the plurality of building floor plan images can include: providing first building floor plan images to a pretrained image vectorizer trained to generate vector graphic representations; receiving vector graphic representations of the first building floor plan images from the pretrained image vectorizer; and including the vector graphic representations of the first building floor plan images in the other sets of training data in association with corresponding first building floor plan images.

As yet another example, automatically generating the plurality of other sets of training data for the at least one artificial intelligence engine based on the plurality of building floor plan images can include: providing first building floor plan images to a footprint generator that is pretrained to generate footprint images of outer walls of buildings included in the building floor plan images; receiving footprint images from the footprint generator; and including the footprint images in the other sets of training data in association with corresponding first building floor plan images. The footprint generator can generate a footprint image for a first building by: generating a pixel mask representing the outer walls of the first building; providing the pixel mask representing the outer walls of the first building to a denoising model; receiving a noise-reduced pixel mask from the denoising model; providing the noise-reduced pixel mask to an image vectorizer; receiving vector graphic representations of the outer walls from the image vectorizer; and using the vector graphic representations to draw the outer walls in the footprint image for the first building. The pixel mask can be generated by a segmentation or a contour detection process.

In some examples, automatically generating the plurality of other sets of training data for the at least one artificial intelligence engine based on the plurality of building floor plan images comprises, for a first building floor plan image, includes: randomly occluding, in different versions of the first building floor plan image, different portions of the first building floor plan image; and including, in the other sets of training data, the different versions of the first building floor plan image.

The different versions of the first building floor plan image and a prompt can be provided to a pretrained model trained to generate natural language descriptions from building floor plan images. Natural language descriptions of the different versions of the first building floor plan image can be received from the pretrained model and included in the other sets of training data. As another example, the different versions of the first building floor plan image can be provided to a pretrained image vectorizer trained to generate vector graphic representations. Vector graphic representations of the different versions of the first building floor plan image can be received from the pretrained image vectorizer and included in the other sets of training data.

At 1106, at least one trained artificial intelligence model is generated by training, using the plurality of building floor plan images and the other sets of training data generated based on the plurality of building floor plan images, the at least one artificial intelligence engine to automatically generate building design specifications.

At 1108, performance specifications for a building are received with a request to automatically generate building design specifications for the building.

At 1110, the at least one trained artificial intelligence model automatically generates building design specifications for the building.

At 1112, the building design specifications for the building are provided in response to the request.

### Other Implementations

A first implementation is described below in the claims. Other implementations may be provided. For instance, a second implementation may include the following examples for a translation layer implementation.

Example 1. A computer-implemented method comprising: receiving requested building performance specifications for a building project at an artificial intelligence system trained to generate building design specifications based on building performance specifications, wherein each requested building performance specification corresponds to a respective performance specification parameter; determining, by the artificial intelligence system, possible bounds for each respective performance specification parameter; determining, by the artificial intelligence system, a model input value for each performance specification parameter based on corresponding possible bounds for the performance specification parameter; providing the model input values for each performance specification parameter to a model of the artificial intelligence system; automatically determining, by the model, building design specifications based on provided model input values; and providing the building design specifications in response to receiving the requested building performance specifications.

Example 2. The computer-implemented method of Example 1, wherein the requested building performance specifications include at least a first building performance specification that requests a maximum or minimum value for a first performance specification parameter.

Example 3. The computer-implemented method of Example 2, wherein determining the possible bounds for the first performance specification parameter comprises determining an upper or lower possible bound for the first performance specification parameter.

Example 4. The computer-implemented method of Example 3, wherein determining the model input value for the first performance specification parameter comprises automatically determining the upper or lower possible bound of the first performance specification parameter as the model input value for the first performance specification parameter.

Example 5. The computer-implemented method of Example 4, wherein determining the upper or lower possible bound of the first performance specification parameter as the model input value for the first performance specification parameter comprises: providing, in response to receiving the requested building performance specifications, the upper or lower possible bound as a suggested model input value for the first performance specification parameter; receiving a confirmation of using the upper or lower possible bound as the model input value; and determining the upper possible or lower possible bound as the model input value for the first performance specification parameter in response to the confirmation.

Example 6. The computer-implemented method of Example 3, wherein determining the model input value for the first performance specification parameter comprises: providing, in response to receiving the requested building performance specifications, the upper or lower possible bound as a suggested model input value for the first performance specification parameter; receiving, as a modified model input value, a modification of the suggested model input value; determining that the modified model input value is within the possible bounds of the first performance specification parameter; and determining the modified model input value as the model input value for the first performance specification parameter.

Example 7. The computer-implemented method of Example 1, wherein the requested building performance specifications include at least a second building performance specification that requests an explicit value for a second performance specification parameter.

Example 8. The computer-implemented method of Example 7, wherein determining the model input value for the second performance specification parameter comprises: determining that the explicit value is within the possible bounds of the second performance specification parameter; and automatically selecting the explicit value as the model input value for the second performance specification parameter in response to determining that the explicit value is within the possible bounds of the second performance specification parameter.

Example 9. The computer-implemented method of Example 7, wherein determining the model input value for the second performance specification parameter comprises: determining that the explicit value is not within the possible bounds of the second performance specification parameter; providing possible bounds information for the second performance specification parameter in response to receiving the requested building performance specifications; receiving a new explicit value for the second performance specification parameter; determining that the new explicit value is within the possible bounds of the second performance specification parameter; and selecting the new explicit value as the model input value for the second performance specification parameter in response to determining that the new explicit value is within the possible bounds of the second performance specification parameter.

Example 10. The computer-implemented method of Example 1, wherein the requested building performance specifications include different relative priorities of different performance specifications.

Example 11. The computer-implemented method of Example 14, wherein determining model input values for the different performance specifications comprises determining model input values for performance specifications with higher relative priorities before determining model input values for performance specifications with lower relative priorities.

Example 12. The computer-implemented method of Example 1, wherein determining the model input value for a first user specification parameter comprises determining the model input value for the first user specification parameter based on training data for the first user specification parameter.

Example 13. The computer-implemented method of Example 12, wherein determining the model input value for a second user specification parameter that has a lower importance value than the first user specification parameter comprises determining the model input value for the second user specification parameter based on training data for the second user specification parameter and the model input value for the first user specification parameter.

Example 14. The computer-implemented of Example 12, wherein determining the model input value for the first user specification parameter comprises: identifying constraints of the building project; generating filtered training data by filtering the training data based on the constraints of the building project and the first user specification parameter; determining the model input value for the first user specification parameter based on a distribution of values for the first user specification parameter in the filtered training data.

Example 15. The computer-implemented method of Example 1, wherein the requested building performance specifications include at least two related building performance specifications that each relate at least in part to a first parameter.

Example 16. The computer-implemented method of Example 15, wherein determining a model input value for the first parameter comprises determining that the model input value for the first parameter satisfies each of the related building performance specifications.

Example 17. The computer-implemented method of Example 1, further comprising: receiving an acceptance of the building design specifications; and generating building plans based on the building design specifications in response to receiving the acceptance of the building design specifications.

A third implementation may include the following examples for a model training, tuning, and adapting implementation.

Example 1. A computer-implemented method comprising: identifying a baseline artificial intelligence model; training the baseline artificial intelligence model using a training dataset to generate a supervised fine-tuned building design generation model configured to generate building design specifications based on building performance specifications; generating a scored preference dataset for the supervised fine-tuned building design generation model; generating an aligned building design generation model by aligning the supervised fine-tuned building design generation model using the scored preference dataset; receiving, at the aligned building design generation model, building performance specifications for a building project; and generating, by the aligned building design generation model, building design specifications for the building project that satisfy received building performance specifications.

Example 2. The computer-implemented method of Example 1, wherein training the baseline artificial intelligence model using the training dataset to generate the supervised fine-tuned building design generation model comprises using training data for existing buildings.

Example 3. The computer-implemented method of Example 1, wherein training the baseline artificial intelligence model using the training dataset to generate the supervised fine-tuned building design generation model comprises using synthetic training data.

Example 4. The computer-implemented method of Example 1, wherein training the baseline artificial intelligence model using the training dataset to generate the supervised fine-tuned building design generation model comprises training the supervised fine-tuned building design generation model in a self-supervised manner on a next token prediction task to learn rules of building designs.

Example 5. The computer-implemented method of Example 1, wherein training the baseline artificial intelligence model using the training dataset to generate the supervised fine-tuned building design generation model comprises training the supervised fine-tuned building design generation model to predict design specifications of buildings based on received performance specifications.

Example 6. The computer-implemented method of Example 1, wherein generating the supervised fine-tuned building design generation model comprises training the supervised fine-tune building design generation model to perform tasks related to a building domain such as geometric manipulation of building designs to improve an understanding of the supervised fine-tuned building design generation model with respect to the building domain.

Example 7. The computer-implemented method of Example 1, wherein aligning the supervised fine-tuned building design generation model includes using one or more of reinforcement learning by human feedback, reinforcement learning with toolset feedback, direct preference optimization, or group relative policy optimization.

Example 8. The computer-implemented method of Example 7, wherein generating the supervised fine-tuned building design generation model comprises training the supervised fine-tune building design generation model with first domain knowledge and wherein aligning the supervised fine-tuned building design generation model comprises further training the supervised fine-tune building design generation model using reinforcement learning using second domain knowledge.

Example 9. The computer-implemented method of Example 8, wherein multiple cycles of supervised fine tuning and reinforcement learning are performed using multiple knowledge domains or knowledge subdomains.

Example 10. The computer-implemented method of Example 1, wherein aligning the supervised fine-tuned building design generation model includes: prompting the supervised fine-tuned building design generation model to generate chain of thought explanations that explain why proposed design specifications were chosen for given performance specifications; and using the chain of thought explanations during the aligning.

A fourth implementation may include the following examples for a model cascade implementation.

Example 1. A computer-implemented system comprising: a transformer model orchestrator; and a sequence of transformer models configured to generate transformer tokens comprising design information, wherein: each transformer model in the sequence is configured to receive, from the transformer model orchestrator, as a first input, constraint information for a building design; each transformer model in the sequence except a last transformer model is configured to provide output generated by the transformer model to a next transformer model in the sequence; each transformer model in the sequence except a first transformer model is configured to: receive, from the transformer model orchestrator, as a second input, output generated by a previous transformer model in the sequence; and generate transformer tokens comprising design information based on the constraint information and the output generated by the previous transformer model in the sequence; and the sequence of transformer models includes at least a structural transformer model configured to generate structural design information, an architectural element transformer model configured to generate interior architectural design information, and a fixtures transformer model configured to generate fixture design information for a design.

Example 2. The computer-implemented system of Example 1, wherein the constraint information comprises at least one of textual constraint information or one or more images.

Example 3. The computer-implemented system of Example 1, wherein the design information generated by the sequence of transformer models comprises floor plan design information.

Example 4. The computer-implemented system of Example 1, further comprising at least one filtering model that filters the constraint information for a given transformer model before constraint information is provided to the given transformer model.

Example 5. The computer-implemented system of Example 1, further comprising a set of modality-specific encoders that are each configured to encode inputs received at a given transformer model and a set of modality-specific decoders that are each configured to decode outputs generated by a given transformer model.

Example 6. The computer-implemented system of Example 5, wherein the set of modality-specific encoders includes an image tokenizer, a text tokenizer, and a vector graphics tokenizer.

Example 7. The computer-implemented system of Example 6, wherein the set of modality-specific decoders includes an image decoder, a text decoder, and a vector graphics decoder.

Example 8. The computer-implemented system of Example 7, wherein the image decoder, the text decoder, and the vector graphics decoder are respectively configured to generate an image, text, or vector graphics based on respective modality-specific transformer tokens of a given transformer.

Example 9. The computer-implemented system of Example 8, wherein the transformer model orchestrator is configured to provide, to a user, in an inference phase, at least one of the image, the text, or the vector graphics.

Example 10. The computer-implemented system of Example 8, wherein the transformer model orchestrator is configured, in a training phase, for a given transformer, to: compare outputs generated by the set of modality decoders to one or more of the constraint information or ground truth data to generate at least one training signal; and providing the at least one training signal to the given transformer to train the given transformer.

Example 11. The computer-implemented system of Example 8, wherein the transformer model orchestrator is configured, in a training phase, to generate training data by: identifying a set of training images; providing the training images and a set of prompts to a large language model to request the large language model to generate natural language descriptions of the training images; providing the training images to an image vectorization model to request the image vectorization model to generate vector graphic representations of the training images; perform computer vision techniques on the training images to extract footprints from the training images; and randomly occluding portions of the training images to generate multiple masked versions of each training image.

Example 12. The computer-implemented system of Example 6, wherein the transformer model orchestrator is configured to combine inputs for a given transformer model into a single sequence.

Example 13. The computer-implemented system of Example 11, wherein the transformer model orchestrator is configured to project an image sequence generated by an image tokenizer into a space of a same dimension as a text sequence generated by a text tokenizer.

Example 14. A computer-implemented method comprising: receiving, by a first a transformer model of a sequence of transformer models each configured to generate transformer tokens comprising building design information, constraint information for a building design; generating, by the first transformer model and based on the constraint information for the building design, first transformer tokens comprising first transformer model output; chaining transformer model output by providing transformer output from earlier models in the sequence as inputs to later transformer models in the sequence, including: providing the constraint information for the building design and the first transformer model output to a second transformer model; generating, by the second transformer model and based on the constraint information for the building design and the first transformer model output, second transformer tokens comprising second transformer model output; and repeating the chaining of transformer model output to at least a third transformer model; and providing transformer model outputs generated from transformer models in the sequence as design information for the building design.

Example 15. The computer-implemented method of Example 14, wherein the sequence of transformer models includes at least a structural transformer model configured to generate structural design information, an architectural element transformer model configured to generate interior architectural design information, and a fixtures transformer model configured to generate fixture design information for a design.

Example 16. The computer-implemented method of Example 15, wherein the first transformer model is the structural transformer model, the second transformer model is the architectural elements transformer model, and the third transformer model is the fixtures transformer model.

Example 17. The computer-implemented method of Example 14, wherein the constraint information comprises at least one of textual constraint information or one or more images.

Example 18. The computer-implemented method of Example 14, wherein the building design information generated by the sequence of transformer models comprises floor plan design information.

Example 19. The computer-implemented method of Example 14, further comprising filtering, using a filtering model, the constraint information for a given transformer model of the sequence before constraint information is provided to the given transformer model.

Example 20. The computer-implemented method of Example 14, further comprising: encoding, by a set of modality-specific encoders, inputs received at a given transformer model; and decoding, by a set of modality-specific decoders, outputs generated by a given transformer model.

Example 21. The computer-implemented method of Example 20, wherein the set of modality-specific encoders includes an image tokenizer, a text tokenizer, and a vector graphics tokenizer.

Example 22. The computer-implemented method of Example 20, wherein the set of modality-specific decoders includes an image decoder, a text decoder, and a vector graphics decoder.

Example 23. The computer-implemented method of Example 22, wherein the image decoder, the text decoder, and the vector graphics decoder are respectively configured to generate an image, text, or vector graphics based on respective modality-specific transformer tokens of a given transformer.

Example 24. The computer-implemented method of Example 23, further comprising providing, to a user in an inference phase, at least one of the image, the text, or the vector graphics.

Example 25. The computer-implemented method of Example 20, further comprising, in a training phase, for a given transformer: comparing outputs generated by the set of modality decoders to the constraint information to generate at least one training signal; and providing the at least one training signal to the given transformer to train the given transformer.

Example 26. The computer-implemented method of Example 20, further comprising, in a training phase: identifying a set of training images; providing the training images and a set of prompts to a large language model to request the large language model to generate natural language descriptions of the training images; providing the training images to an image vectorization model to request the image vectorization model to generate vector graphic representations of the training images; performing computer vision techniques on the training images to extract footprints from the training images; and randomly occluding portions of the training images to generate multiple masked versions of each training image.

Example 27. The computer-implemented method of Example 14, further comprising combining inputs for a given transformer model into a single sequence.

Example 28. The computer-implemented method of Example 27, further comprising projecting an image sequence generated by an image tokenizer into a space of a same dimension as a text sequence generated by a text tokenizer.

A fifth implementation may include the following examples for training models of a model cascade implementation.

Example 1. A computer-implemented method comprising: obtaining, as training data for at least one artificial intelligence engine, a plurality of building floor plan images; automatically generating a plurality of other sets of training data for the at least one artificial intelligence engine based on the plurality of building floor plan images; generating at least one trained artificial intelligence model by training, using the plurality of building floor plan images and the other sets of training data generated based on the plurality of building floor plan images, the at least one artificial intelligence engine to automatically generate building design specifications; receiving performance specifications for a building with a request to automatically generate building design specifications for the building; automatically generating, by the at least one trained artificial intelligence model, building design specifications for the building; and providing the building design specifications for the building in response to the request.

Example 2. The computer-implemented method of Example 1, wherein automatically generating the plurality of other sets of training data for the at least one artificial intelligence engine based on the plurality of building floor plan images comprises: providing first building floor plan images and a prompt to a pretrained model trained to generate natural language descriptions from building floor plan images; receiving natural language descriptions of the first building floor plan images from the pretrained model; and including the natural language descriptions in the other sets of training data in association with corresponding first building floor plan images.

Example 3. The computer-implemented method of Example 1, wherein automatically generating the plurality of other sets of training data for the at least one artificial intelligence engine based on the plurality of building floor plan images comprises: providing first building floor plan images to a pretrained image vectorizer trained to generate vector graphic representations; receiving vector graphic representations of the first building floor plan images from the pretrained image vectorizer; and including the vector graphic representations of the first building floor plan images in the other sets of training data in association with corresponding first building floor plan images.

Example 4. The computer-implemented method of Example 1, wherein automatically generating the plurality of other sets of training data for the at least one artificial intelligence engine based on the plurality of building floor plan images comprises: providing first building floor plan images to a footprint generator that is pretrained to generate footprint images of outer walls of buildings included in the building floor plan images; receiving footprint images from the footprint generator; and including the footprint images in the other sets of training data in association with corresponding first building floor plan images.

Example 5. The computer-implemented method of Example 4, wherein the footprint generator generates a footprint image for a first building, by: generating a pixel mask representing the outer walls of the first building; providing the pixel mask representing the outer walls of the first building to a denoising model; receiving a noise-reduced pixel mask from the denoising model; providing the noise-reduced pixel mask to an image vectorizer; receiving vector graphic representations of the outer walls from the image vectorizer; and using the vector graphic representations to draw the outer walls in the footprint image for the first building.

Example 6. The computer-implemented method of Example 5, wherein the pixel mask is generated by a segmentation or a contour detection process.

Example 7. The computer-implemented method of Example 1, wherein automatically generating the plurality of other sets of training data for the at least one artificial intelligence engine based on the plurality of building floor plan images comprises, for a first building floor plan image, includes: randomly occluding, in different versions of the first building floor plan image, different portions of the first building floor plan image; and including, in the other sets of training data, the different versions of the first building floor plan image.

Example 8. The computer-implemented method of Example 7, further comprising providing the different versions of the first building floor plan image and a prompt to a pretrained model trained to generate natural language descriptions from building floor plan images; receiving natural language descriptions of the different versions of the first building floor plan image from the pretrained model; and including the natural language descriptions of the different versions of the first building floor plan image in the other sets of training data.

Example 9. The computer-implemented method of Example 7, further comprising providing the different versions of the first building floor plan image to a pretrained image vectorizer trained to generate vector graphic representations; receiving vector graphic representations of the different versions of the first building floor plan image from the pretrained image vectorizer; and including the vector graphic representations of the different versions of the first building floor plan image in the other sets of training data.

Implementations of the subject matter and the functional operations described in this specification can be implemented in digital electronic circuitry, in tangibly-implemented computer software or firmware, in computer hardware, including the structures disclosed in this specification and their structural equivalents, or in combinations of one or more of them. Implementations of the subject matter described in this specification can be implemented as one or more computer programs, i.e., one or more modules of computer program instructions encoded on a tangible non-transitory program carrier for execution by, or to control the operation of, data processing apparatus. The computer storage medium can be a machine-readable storage device, a machine-readable storage substrate, a random or serial access memory device, or a combination of one or more of them.

The term “data processing apparatus” refers to data processing hardware and encompasses all kinds of apparatus, devices, and machines for processing data, including, by way of example, a programmable processor, a computer, or multiple processors or computers. The apparatus can also be or further include special purpose logic circuitry, e.g., a central processing unit (CPU), an FPGA (field programmable gate array), or an ASIC (application-specific integrated circuit). In some implementations, the data processing apparatus and/or special purpose logic circuitry may be hardware-based and/or software-based. The apparatus can optionally include code that creates an execution environment for computer programs, e.g., code that constitutes processor firmware, a protocol stack, a database management system, an operating system, or a combination of one or more of them. The present disclosure contemplates the use of data processing apparatuses with or without conventional operating systems, for example Linux, UNIX, Windows, Mac OS, Android, iOS or any other suitable conventional operating system.

A computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a communication network. While portions of the programs illustrated in the various figures are shown as individual modules that implement the various features and functionality through various objects, methods, or other processes, the programs may instead include a number of sub-modules, third party services, components, libraries, and such, as appropriate. Conversely, the features and functionality of various components can be combined into single components as appropriate.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., a central processing unit (CPU), a FPGA (field programmable gate array), or an ASIC (application-specific integrated circuit).

Computers suitable for the execution of a computer program include, by way of example, and can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media (transitory or non-transitory, as appropriate) suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The memory may store various objects or data, including caches, classes, frameworks, applications, backup data, jobs, web pages, web page templates, database tables, repositories storing business and/or dynamic information, and any other appropriate information including any parameters, variables, algorithms, instructions, rules, constraints, or references thereto. Additionally, the memory may include any other appropriate data, such as logs, policies, security or access data, reporting files, as well as others. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube), LCD (liquid crystal display), or plasma monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

The term “graphical user interface,” or GUI, may be used in the singular or the plural to describe one or more graphical user interfaces and each of the displays of a particular graphical user interface. Therefore, a GUI may represent any graphical user interface, including but not limited to, a web browser, a touch screen, or a command line interface (CLI) that processes information and efficiently presents the information results to the user. In general, a GUI may include a plurality of user interface (UI) elements, some or all associated with a web browser, such as interactive fields, pull-down lists, and buttons operable by the business suite user. These and other UI elements may be related to or represent the functions of the web browser.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN), a wide area network (WAN), e.g., the Internet, and a wireless local area network (WLAN).

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of sub-combinations.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be helpful. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations, alterations, and permutations of the described implementations are within the scope of the following claims as will be apparent to those skilled in the art. For example, the actions recited in the claims can be performed in a different order and still achieve desirable results.

Accordingly, the above description of example implementations does not define or constrain this disclosure. Other changes, substitutions, and alterations are also possible without departing from the spirit and scope of this disclosure.

What is claimed is:

1. A computer-implemented method comprising:
obtaining, as building design artificial intelligence model training data, building design data for a plurality of buildings;
enhancing the building design artificial intelligence model training data to include building performance specification data corresponding to obtained building design data;
training an artificial intelligence model using the building design artificial intelligence model training data to generate building design specifications based on building performance specifications and to translate building performance specifications into corresponding viable building performance specifications;
receiving building performance specifications for a building project, wherein each requested building performance specification corresponds to a respective performance specification parameter;
translating, using the artificial intelligence model and the building design artificial intelligence model training data, at least a first building performance specification into a first viable building performance specification parameter value;
providing the building performance specifications, including the first viable building performance specification parameter value, to the artificial intelligence model that is trained to generate building design specifications based on building performance specifications;
generating, by the artificial intelligence model, building designs for the building project that satisfy the building performance specifications; and
providing the building designs for the building project for evaluation and construction of the building project.

2. The computer-implemented method of claim 1, wherein obtaining building design data comprising obtaining building design data for existing buildings.

3. The computer-implemented method of claim 1, wherein obtaining building design data comprises generating synthetic data for synthetically-designed buildings.

4. The computer-implemented method of claim 3, wherein generating synthetic data comprises generating the synthetic data based on a set of rules that includes rules for how buildings can be composed.

5. The computer-implemented method of claim 1, wherein enhancing the building design artificial intelligence model training data comprises determining the building performance specifications for obtained building design data and associating determined performance specifications, in the building design artificial intelligence model training data, with corresponding building design information.

6. The computer-implemented method of claim 1, wherein the artificial intelligence model is trained to generate different kinds of building designs, including structural, architectural, and fixtures-related designs.

7. The computer-implemented method of claim 1, wherein the artificial intelligence model is trained to generate one kind of building design information selected from at least structural, architectural, and fixtures-related designs.

8. The computer-implemented method of claim 7, wherein the artificial intelligence model is included with other artificial intelligence models in a model cascade in which outputs of some artificial intelligence models are provided as inputs to other artificial intelligence models.

9. The computer-implemented method of claim 1, wherein received performance specifications include multi-modal information comprising at least textual and image inputs.

10. The computer-implemented method of claim 1, wherein at least some of the building design specifications include vector representations.

11. The computer-implemented method of claim 10, further comprising providing the vector representations to a performance evaluation system that evaluates performance of the building design specifications.

12. A system comprising one or more computers and one or more storage devices on which are stored instructions that are operable, when executed by the one or more computers, to cause the one or more computers to perform operations comprising:
obtaining, as building design artificial intelligence model training data, building design data for a plurality of buildings;
enhancing the building design artificial intelligence model training data to include building performance specification data corresponding to obtained building design data;
training an artificial intelligence model using the building design artificial intelligence model training data to generate building design specifications based on building performance specifications and to translate building performance specifications into corresponding viable building performance specifications;
receiving building performance specifications for a building project, wherein each requested building performance specification corresponds to a respective performance specification parameter;
translating, using the artificial intelligence model and the building design artificial intelligence model training data, at least a first building performance specification into a first viable building performance specification parameter value;
providing the building performance specifications, including the first viable building performance specification parameter value, to the artificial intelligence model that is trained to generate building design specifications based on building performance specifications;
generating, by the artificial intelligence model, building designs for the building project that satisfy the building performance specifications; and
providing the building designs for the building project for evaluation and construction of the building project.

13. The system of claim 12, wherein obtaining building design data comprising obtaining building design data for existing buildings.

14. The system of claim 12, wherein obtaining building design data comprises generating synthetic data for synthetically-designed buildings.

15. The system of claim 14, wherein generating synthetic data comprises generating the synthetic data based on a set of rules that includes rules for how buildings can be composed.

16. One or more computer-readable storage media encoded with instructions that, when executed by one or more computers, cause the one or more computers to perform operations comprising:
obtaining, as building design artificial intelligence model training data, building design data for a plurality of buildings;
enhancing the building design artificial intelligence model training data to include building performance specification data corresponding to obtained building design data;
training an artificial intelligence model using the building design artificial intelligence model training data to generate building design specifications based on building performance specifications and to translate building performance specifications into corresponding viable building performance specifications;
receiving building performance specifications for a building project, wherein each requested building performance specification corresponds to a respective performance specification parameter;
translating, using the artificial intelligence model and the building design artificial intelligence model training data, at least a first building performance specification into a corresponding first viable building performance specification parameter value;
providing the building performance specifications, including the corresponding first viable building performance specification parameter value, to the artificial intelligence model that is trained to generate building design specifications based on building performance specifications;
generating, by the artificial intelligence model, building designs for the building project that satisfy the building performance specifications; and
providing the building designs for the building project for evaluation and construction of the building project.

17. The computer-readable storage media of claim 16, wherein obtaining building design data comprising obtaining building design data for existing buildings.

18. The computer-readable storage media of claim 16, wherein obtaining building design data comprises generating synthetic data for synthetically-designed buildings.

19. The computer-readable storage media of claim 18, wherein generating synthetic data comprises generating the synthetic data based on a set of rules that includes rules for how buildings can be composed.

20. The computer-readable storage media of claim 16, wherein enhancing the building design artificial intelligence model training data comprises determining the building performance specifications for obtained building design data and associating determined performance specifications, in the building design artificial intelligence model training data, with corresponding building design information.

21. The computer-implemented method of claim 1, wherein the building performance specifications include at least a first building performance specification that requests a maximum or minimum value for a first performance specification parameter.

22. The computer-implemented method of claim 21, further comprising:
determining, by the artificial intelligence model, possible bounds for each respective performance specification parameter; and
determining, by the artificial intelligence model, a viable performance specification parameter value for each performance specification parameter based on corresponding possible bounds for the performance specification parameter.

23. The computer-implemented method of claim 22, wherein determining the possible bounds for the first performance specification parameter comprises determining an upper or lower possible bound for the first performance specification parameter.

24. The computer-implemented method of claim 23, wherein determining the viable performance specification parameter value for the first performance specification parameter comprises automatically determining the upper or lower possible bound of the first performance specification parameter as the viable performance specification parameter value for the first performance specification parameter.

25. The computer-implemented method of claim 24, wherein determining the upper or lower possible bound of the first performance specification parameter as the viable performance specification parameter value for the first performance specification parameter comprises:
providing, in response to receiving the building performance specifications, the upper or lower possible bound as a suggested parameter value for the first performance specification parameter;
receiving a confirmation of using the upper or lower possible bound as a parameter value for the first performance specification parameter; and
determining the upper possible or lower possible bound as the viable performance specification parameter value for the first performance specification parameter in response to the confirmation.

26. The computer-implemented method of claim 23, wherein determining the viable performance specification parameter value for the first performance specification parameter comprises:
providing, in response to receiving the building performance specifications, the upper or lower possible bound as a suggested parameter value for the first performance specification parameter;
receiving, as a modified parameter value, a modification of the suggested parameter value;
determining that the modified parameter value is within the possible bounds of the first performance specification parameter; and
determining the modified parameter value as the viable performance specification parameter value for the first performance specification parameter.

27. The computer-implemented method of claim 22, wherein the building performance specifications include at least a second building performance specification that requests an explicit value for a second performance specification parameter.

28. The computer-implemented method of claim 27, wherein determining the viable performance specification parameter value for the second performance specification parameter comprises:
determining that the explicit value is within the possible bounds of the second performance specification parameter; and
automatically selecting the explicit value as the viable performance specification parameter value for the second performance specification parameter in response to determining that the explicit value is within the possible bounds of the second performance specification parameter.

29. The computer-implemented method of claim 27, wherein determining the viable performance specification parameter value for the second performance specification parameter comprises:
determining that the explicit value is not within the possible bounds of the second performance specification parameter;
providing possible bounds information for the second performance specification parameter in response to receiving the building performance specifications;
receiving a new explicit value for the second performance specification parameter;
determining that the new explicit value is within the possible bounds of the second performance specification parameter; and
selecting the new explicit value as the viable performance specification parameter value for the second performance specification parameter in response to determining that the new explicit value is within the possible bounds of the second performance specification parameter.

30. The computer-implemented method of claim 1, wherein translating comprises determining, by the artificial intelligence model and using multiple iterations, different respective building specification parameter values for multiple different respective building specification parameters.

31. The computer-implemented method of claim 1, wherein the building performance specifications include different relative priorities of different building performance specification parameters.

32. The computer-implemented method of claim 31, wherein determining viable building performance specification parameter values for the different building performance specification parameters comprises determining viable performance specification parameter values for building performance specification parameters with higher relative priorities before determining viable building performance specification parameter values for building performance specification parameters with lower relative priorities.

33. The computer-implemented method of claim 32, wherein determining a viable building performance specification parameter value for a first building performance specification parameter comprises determining the viable building performance specification parameter value for the first building performance specification parameter based on training data for the first building performance specification parameter.

34. The computer-implemented method of claim 33, wherein determining the viable building performance specification parameter value for a second building performance specification parameter that has a lower importance value than the first building performance specification parameter comprises determining the viable building performance specification parameter value for the second building performance specification parameter based both on training data for the second building performance specification parameter and the viable building performance specification parameter value previously determined by the artificial intelligence model for the first building performance specification parameter.

35. The computer-implemented method of claim 33, wherein determining the viable building performance specification parameter value for the first building performance specification parameter comprises:
identifying constraints of the building project;
generating filtered training data by filtering the building design artificial intelligence model training data based on the constraints of the building project and the first building performance specification parameter; and
determining the viable building performance specification parameter value for the first building performance specification parameter based on a distribution of values for the first building performance specification parameter in the filtered training data.

36. The computer-implemented method of claim 35, further comprising:
determining, by the artificial intelligence model, possible bounds for the first building performance specification parameter based on the distribution of values for the first building performance specification parameter in the filtered training data; and
selecting, by the artificial intelligence model, the viable building performance specification parameter value for the first building performance specification parameter based on the possible bounds for the first building performance specification parameter.
